(19) United States
(12) Patent Application Publication
(10) Pub. No.: US 2025/0338568 A1
(43) Pub. Date: Oct. 30, 2025

(54) SEMICONDUCTOR DEVICE AND METHOD OF MANUFACTURING THE SAME

(71) Applicant: Renesas Electronics Corporation, Tokyo (JP)

(72) Inventor: Kazuya KAMON, Tokyo (JP)

(21) Appl. No.: 19/171,415

(22) Filed: Apr. 7, 2025

(30) Foreign Application Priority Data
Apr. 24, 2024 (JP) 2024-070635

(51) Int. Cl. H10D 62/10; H01L 21/02; H01L 21/762; H10D 30/01; H10D 30/60

(52) U.S. Cl. CPC H10D 62/102; H01L 21/02181; H01L 21/02186; H01L 21/02189; H01L 21/02194; H01L 21/76224; H10D 30/0227; H10D 30/601; H10D 62/113

(57) ABSTRACT

A semiconductor device has an interlayer insulation film made of antiferroelectric. The minimum value of a relative dielectric constant of the interlayer insulation film is less than 2.

### CROSS-REFERENCE TO RELATED APPLICATIONS

The present application claims priority from Japanese Patent Application No. 2024-70635 filed on Apr. 24, 2024, the content of which is hereby incorporated by reference to this application.

### BACKGROUND

The present disclosure relates to a semiconductor device and a method of manufacturing the same.

In a semiconductor device, as a semiconductor element is highly integrated, a multilayer wiring technique is adopted and miniaturization of each wiring progresses. As a result, a problem about a propagation delay of an As measures of this electrical signal becomes apparent. propagation delay, in order to reduce capacitance between wirings that sandwiches an interlayer insulation film, a low dielectric constant material (Low-k material) as a material for configurating the interlayer insulation film is explored. A dielectric constant k of the low dielectric constant material is put into practical use as the interlayer insulation film is about 2.6 or more and 2.9 or less.

There is disclosed a technique listed below.
[Patent Document 1] Japanese Unexamined Patent Application Publication No. 2009-004408

Patent Document 1 discloses a wiring structure that is composed of a low dielectric constant insulation film and a wiring embedded in a wiring trench formed in the insulation film.

### SUMMARY

Recently, a semiconductor device is required to further reduce inter-wiring capacitance and, as a result, the material that is further lower in relative dielectric constant than SiOCH is explored as the material configurating the interlayer insulation film.

Other problems and novel features will be apparent from the present specification and the accompanying drawings.

A semiconductor device according one embodiment includes an interlayer insulation film made of antiferroelectric. The minimum value of the relative dielectric constant of the interlayer insulation film is less than 2.

A semiconductor device according to another embodiment includes a semiconductor substrate having a first surface, a gate electrode formed on the first surface via a gate insulation film, a sidewall insulation film covering a side wall of each of the gate insulation film and the gate electrode, and an interlayer insulation film formed on the first surface so as to cover the gate electrode and the sidewall insulation film. The interlayer insulation film is made of antiferroelectric. The interlayer insulation film is spaced from the gate insulation film.

A method of manufacturing a semiconductor device includes a first step of forming a semiconductor element on a first surface of a semiconductor substrate, and a second step of forming an interlayer insulation film, which covers the semiconductor element, on the first surface. The interlayer insulation film is made of antiferroelectric. In the second step, a temperature of the interlayer insulation film is set less than the Curie point of the antiferroelectric.

According to the present disclosure, the following semiconductor device can be provided; an inter-wiring capacitance can be reduced in comparison with a semiconductor device having an interlayer insulation film made of SiOCH.

### BRIEF DESCRIPTION OF THE DRAWINGS

FIG. 1 is a plan view showing a configuration example of a semiconductor device according to a first embodiment.

FIG. 2 is a partially enlarged plan view showing a configuration example of a semiconductor element including the semiconductor device according to the first embodiment.

FIG. 3 is a cross-sectional view of the semiconductor element shown in FIG. 2.

FIG. 4 is a graph showing a relationship between an electric field and polarization of antiferroelectric that is obtained from a simulation.

FIG. 5 is a graph showing a relationship between an electric field and a relative dielectric constant of antiferroelectric that is obtained from a simulation.

FIG. 6 is a flowchart showing one example of a method of manufacturing a semiconductor device according to the first embodiment.

FIG. 7 is a circuit diagram showing one example of a circuit realized when an ESD pulse enters the semiconductor device according to the first embodiment.

FIG. 8 is a graph showing a time change of a current flowing in a MOS transistor after the ESD pulse enters the semiconductor device according to the first embodiment.

FIG. 9 is a cross-sectional view showing a configuration example of a semiconductor device according to a second embodiment.

FIG. 10 is a circuit diagram showing one example of a circuit realized when an ESD pulse enters the semiconductor device according to the second embodiment.

FIG. 11 is a partially enlarged plan view showing a configuration example of a semiconductor element included in a semiconductor device according to a third embodiment.

FIG. 12 is a partially enlarged plan view showing a configuration example of a semiconductor element included in a semiconductor device according to a fourth embodiment.

### DETAILED DESCRIPTION

Hereinafter, embodiments will be explained with reference to the drawings. Note that in the drawings described later, the same reference numerals are denoted to the same or corresponding parts, and a description thereof will be not repeated.

### First Embodiment

### Configuration of Semiconductor Device

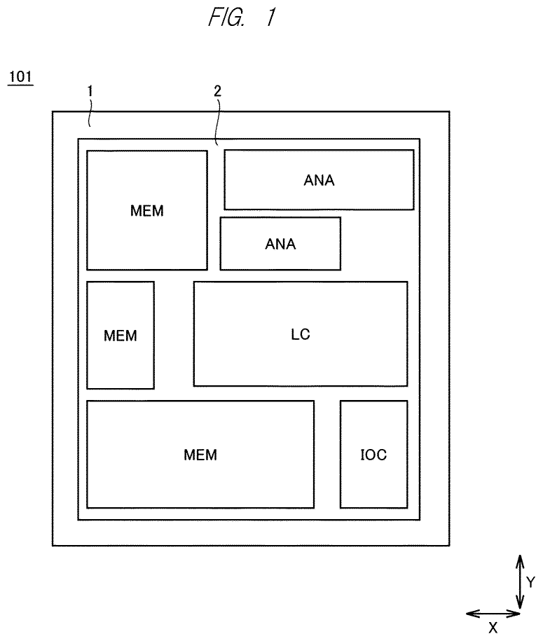

FIG. 1 is a plan view of a semiconductor device 101 according to a first embodiment. As shown in FIG. 1, the semiconductor device 101 according to the first embodiment has a scribe region 1 and a module region 2. The scribe region 1 has an outer circumference of the semiconductor device 101 formed by a scribe processing with respect to a semiconductor substrate. The module region 2 is formed inside from the scribe region 1 in a plan view. The module region 2 has, for example, an input/output circuit IOC, an analog circuit ANA, a logic circuit LC, and a memory circuit MEM. The memory circuit MEM has a plurality of memory cells.

The module region 2 includes a plurality of semiconductor elements. The plurality of semiconductor elements includes at least any of a transistor and a diode. The plurality of semiconductor elements includes, for example, a vertical insulation gate field effect transistor. The insulation gate field effect transistor is, for example, a Metal Insulator Semiconductor (MIS) transistor. The MIS transistor is, for example, a Metal Oxide Semiconductor (MOS) transistor. The MOS transistor is included in each of the plurality of memory cells within the memory circuit MEM. Note that the semiconductor element included in the module region 2 is not limited particularly.

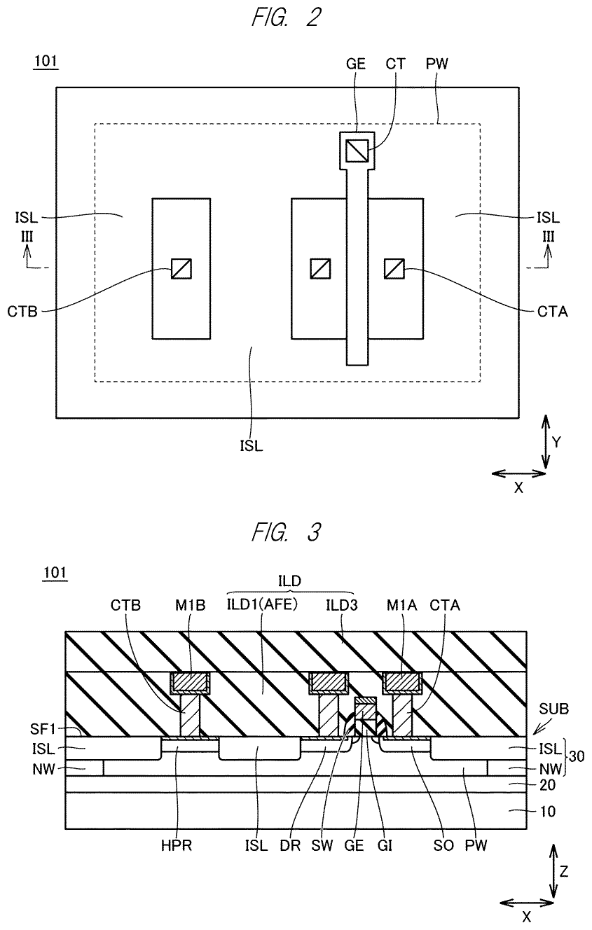

FIG. 2 is a partially enlarged plan view showing the MOS transistor included in one memory cell within the semiconductor device 101. FIG. 3 is a cross-sectional view seen from an arrow III-III in FIG. 2. As shown in FIG. 2, the semiconductor device 101 is formed by using a semiconductor substrate SUB. The semiconductor substrate

SUB has a first surface SF1. A MOS transistor TR is formed on the first surface SF1.

In the present specification, two directions that are directions along the first surface SF1 and are orthogonal to each other is described as a X direction and a Y direction. A direction orthogonal to the first surface SF1 is described as a Z direction. In the Z direction, a direction directed to a bulk layer 10 from a single crystal layer 30 is described as a lower direction. In the Z direction, a point of view seen from above is described as a plan view.

The semiconductor substrate SUB is, for example, a Silicon On Insulator (SOI) substrate. The SOI substrate has the bulk layer 10, a substrate separation film 20, and the single crustal layer 30. The bulk layer 10, the substrate separation film 20, and the single crystal layer 30 are laminated in the Z direction in this order. The substrate separation film 20 is disposed between the bulk layer 10 and the single crystal layer 30. A material made of the bulk layer 10 is, for example, a P-type silicon single crystal. The substrate separation film 20 is, for example, a Buried Oxide (BOX) A material film. made of the substrate separation film 20 is, for example, an n-type silicon oxide film. A material made of the single crystal layer 30 is, for example, a silicon single crystal. The single crystal layer 30 has a p-type well PW, a drain DR and a source SO that are n-type impurity region, a channel region between the drain DR and the source SO, and the like. Note that the semiconductor substrate SUB of the semiconductor device 101 is not limited to the SOI substrate.

The MOS transistor TR1 is, for example, an N-channel WOS (NMOS) transistor. The MOS transistor TR1 includes a p-type well PW, the source SO and the drain DR that are the n-type impurity region, the channel region between the source SO and the drain DR, and a gate electrode GE. The p-type well PW, the source SO and the drain DR, and the channel region are formed on the single crystal layer 30. The source SO and the drain DR are spaced in the X direction. The gate electrode GE is formed above the channel region via a gate insulation film GI. A sidewall insulation film SW is formed on sidewalls of the gate insulation film GI and the gate electrode GE. The sidewall insulation film SW includes, for example, at least any of a silicon oxide film and a silicon nitride film. Each of the source CE and the drain DR is connected to a plurality of first wiring layer MIA described later via a first contact CT layer CIA. Each of the source SO and the drain DR may have a Lightly Doped Drain (LDD) structure. Note that the MOS transistor TR1 may be a P-channel MOS (PMOS) transistor.

The semiconductor device 101 further has a contact element for fixing a potential of the p-type well PW. The contact element is arranged alongside the MOS transistor in the X direction. The above contact element includes, for example, a p-type impurity region HPR and a second contact CTB. The p-type impurity region HPR is formed on the p-type well PW. The second contact CTB is connected to the p-type impurity region HPR. The second contact CTB is spaced from, for example, the first contact CTA in the X direction.

The semiconductor device 101 further has an element separation film ISL. The element separation film ISL is formed, for example, between the MOS transistors adjacent to each other in the X direction or in the Y direction and between the MOS transistor TR and the contact element. The element separation film ISL is arranged so as to surround the MOS transistor TR and the contact element in a plan view. The MOS transistor TRI is electrically separated from each of another semiconductor device and the contact element by the element separation film ISL. The element separation film ISL has, for example, a Shallow Trench Isolation (STI) structure. The element separation film ISL is, for example, a silicon oxide film.

The semiconductor device 101 further has a plurality of wiring layers M, a plurality of interlayer insulation films ILD, and a plurality of contacts CT. The plurality of wiring layers M and the plurality of interlayer insulation films ILD are laminated in the Z direction. The plurality of wiring layers M is arranged on a upper surface of each of the plurality of interlayer isolation film ILD or in a wiring trench formed on the upper surface of each of the plurality of interlayer insulation films ILD. Each of the plurality of wiring layers M may be formed by a damascene method. A though-hole is formed on and in each of the plurality of interlayer insulation films ILD. Each of the plurality of contacts CT is formed in the through-hole.

The plurality of interlayer insulation film ILD has a lower interlayer insulation film ILD1 located at the lowermost position, an upper interlayer insulation film ILD2 located at the uppermost position, and at least one middle interlayer insulation film ILD3 located between the lower interlayer insulation film ILD1 and the upper interlayer insulation film ILD2.

The lower interlayer insulation film ILD1 is formed on the first surface SF1 so as to cover the gate electrode GE and the sidewall insulation film SW. The lower interlayer insulation film ILD1 contacts with, for example, the gate electrode GE, the sidewall insulation film SW, and the element separation film ISL. The lower interlayer insulation film ILDI contacts with, for example, the source SO and the drain DR. the lower interlayer insulation film ILD1 does not contact with the gate insulation film GI.

The plurality of wiring layers M has a lower wiring layer M1 located at the lowermost position, an upper wiring layer located at the uppermost position, and at least one middle wiring layer located between the lower wiring layer M1 and the upper wiring layer.

The lower wiring layer M1 is disposed on an upper surface of the lower interlayer insulation film ILD1 or in a trench formed on and in the above upper surface, the lower wiring layer M1 includes a plurality of first wiring layers M1A and a plurality of wiring layers M1B that are spaced from each other in the at least any of X direction and the Y direction. Each of the plurality of first wiring layers M1A is connected to the drain DR or the source SO of the MOS transistor TR via the first contact CTA. The second wiring layer M1B is connected to the p-type well PW via the second contact CTB. The first contact CTA and the second contact CTB are formed in the through-hole formed in the lower interlayer insulation film ILD1.

The upper wiring layer is formed on the upper interlayer insulation film. The upper wiring layer includes a pad. Each of the plurality of interlayer insulation films ILD overlaps with the pad in the Z direction.

The lower interlayer insulation film ILD1 is made of antiferroelectric AFD. In a case in which an external electric field is not applied to the antiferroelectric, each of a plurality of sublattices in a crystal has a dielectric polarization. However, since the two sublattices adjacent to each other have the dielectric polarizations in directions opposing to each other, each of the plurality of sublattices hardly has the polarization as a whole crystal. From a different point of view, in the state in which the external electric field is not applied, the entire electric susceptibility χ of the antiferroelectric configurating the lower interlayer insulation film ILD1 is lower than electric susceptibility of a general lower dielectric constant material. The lower interlayer insulation film ILD1 is made of antiferroelectric whose electric susceptibility χ is less than 1 as a whole. Namely, the minimum value of a relative dielectric constant of the lower interlayer insulation film ILD1 is less than 2. Note that SioCH, metal-containing SiO₂, parylene, polyaryl ether, and the like are given as a general low dielectric constant material. Those relative dielectric constants are 2.6 or more and 2.9 or less.

The material configurating the lower interlayer insulation film ILD1 is at least any selected from a group of HFO₂, ZrO₂, Pb(In_{0.5}Nb_{0.5})O₃, NbNaO₃, ZrPbO₃, TiZrLaPbO₃, TiZrPbO₃, NH₄H2PO₄, or NH₄H₂AsO₄.

The antiferroelectric configurating the lower interlayer insulation fil ILD1 preferably has an amorphous structure or a polycrystalline structure. Or, the antiferroelectric configurating the lower interlayer insulation film ILD1 may be relaxor dielectric. In those cases, the entire electric susceptibility χ of the antiferroelectric configuration the lower interlayer insulation film ILD1 substantially becomes zero. Therefore, the minimum value of the relative dielectric constant of the lower interlayer insulation film ILD1 substantially becomes 1.

The maximum value of the relative dielectric of the lower interlayer insulation film ILD1 is more than 2.9. The maximum value of the relative dielectric of the lower interlayer insulation film ILDI is preferably 4.3 or more.

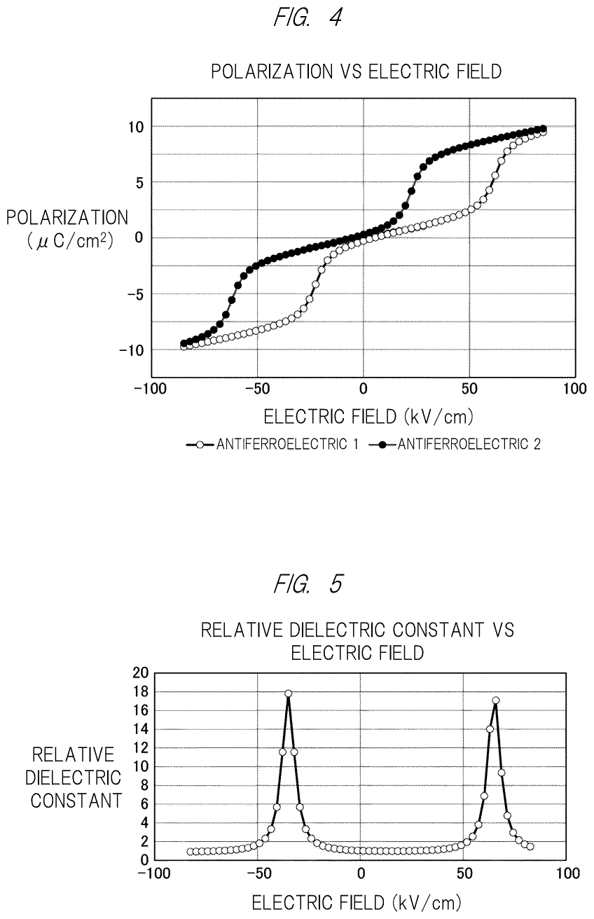

FIG. 4 is a graph showing a relationship between an electric field and polarization of 2-trichloromethylbenzimidaizole (TCMBI) as one example of antiferroelectric that are found by a simulation. A marginal element method has been used as the simulation. White circles in FIG. 4 shows the above relationship when an applied voltage is increased from a negative side to a positive side, and black circles in FIG. 4 shows the above relationship when the applied voltage is decreased from the positive side to the negative side. As shown in FIG. 4, a polarization-electric field curve of the antiferroelectric configurating the lower interlayer insulation film ILD1 shows a double hysteresis loop. As shown in FIG. 4, when the external electric field applied to the antiferroelectric is smaller than specific magnitude, the polarization occurs in the antiferroelectric similarly to paraelectric. When the external electric field applied to the antiferroelectric is equal to or more than the specific magnitude, directions of the respective polarizations of the plurality of sublattices in the antiferroelectric are aligned in the antiferroelectric similarly to the ferroelectric, and the polarizations (spontaneous polarization) occur spontaneously. In this case, the relative dielectric of the antiferroelectric becomes more than 2.9, for example, becomes more than 4.0. A polarization amount (remnant polarization amount) of the antiferroelectric when the external electric field applied to the antiferroelectric is set to zero becomes 15 μC/cm² or less. Namely, the remnant polarization amount of the antiferroelectric becomes almost zero. Note that the spontaneous polarization and the remnant polarization of the lower interlayer insulation film ILD1 can be determined, for example, based on a D-E curve obtained by measuring an electric flux density when an electric field E is applied to the lower interlayer insulation film ILD1.

FIG. 5 is a graph showing, about one example of the antiferroelectric shown in FIG. 4, a relationship between an electric field and a relative dielectric constant when the electric field to be applied gradually increases, the relationship being found by the above simulation. As shown in FIG. 5, the relative dielectric constant of the antiferroelectric configurating the lower interlayer insulation film ILD1 is kept less than 2 until the magnitude of the electric field exceeds a specific value, and it becomes more than 2.9 when the magnitude of the electric field exceeds the specific value. The above specific value is, for example, 50 kV/cm or more and 70 kV/cm or less.

In the semiconductor device 101, during normal operation, the electric field applied between one pair of conductors via the lower interlayer insulation film ILD1 is set to the electric field or less in which the spontaneous polarization occurs in the antiferroelectric.

In the present specification, the normal operation of the semiconductor device means a normal operation predetermined at the semiconductor device and an operation at a state in which electric charges due to cosmic rays, Electric-Static Discharges (ESD), and the like do not occur. In the present specification, the cosmic rays mean radiation coming from an outer space or particles caused due to the radiation, the radiation or particles having energy of several MeV to GeV. The cosmic rays are particle radiation or high energy electromagnetic radiation. The particle radiation is, for example, alpha rays, beta rays, a neutron beam, or a proton beam. The electromagnetic radiation is, for example, gamma rays or X rays. The above particles due to the radiation is, for example, neutron occurring by colliding with atomic nucleus of oxygen, nitrogen, or the like when the above cosmic rays enter the atmosphere.

In the semiconductor device 101, an electric field applied to the lower interlayer insulation film ILD1 due to the cosmic rays is less than an electric field which causes the antiferroelectric configurating the lower interlayer insulation film ILD1 to undergo a phase transition to ferroelectric. The electric field applied to the lower interlayer insulation film ILDI due to the ESD is preferably less than electric causes the the field which antiferroelectric configurating the lower interlayer insulation film ILD1 to undergo a phase transition to the ferroelectric.

In the lower interlayer insulation film ILD1, a plurality of voids is not formed. The lower interlayer insulation film ILD1 includes no porous material. Young's modulus of the lower interlayer insulation film ILD1 is higher than Young's modulus of a low dielectric constant material of the porous material. The Young's modulus of the lower interlayer insulation film ILD1 is 8 GPa or more.

A film thickness of the lower interlayer insulation film ILD1 is 2 nm or more and less than 50 nm. The film thickness of the lower interlayer insulation film ILD1 is a size of the lower interlayer insulation film ILD1 in the Z direction.

### Method of Manufacturing Semiconductor Device

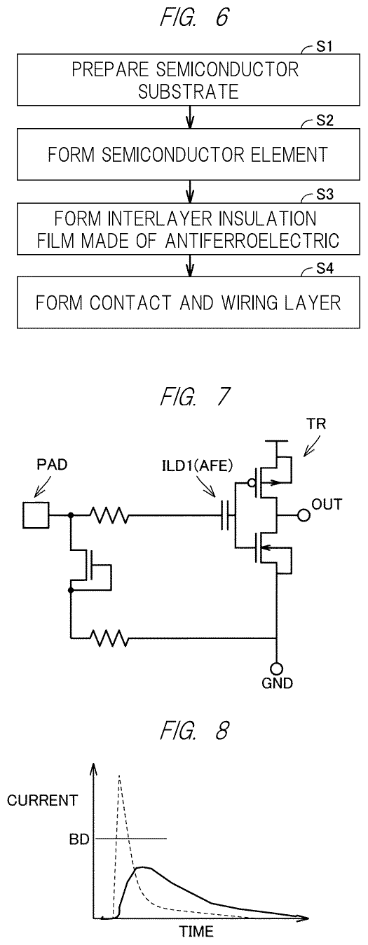

Hereinafter, one example of a method of manufacturing the semiconductor device 101 will be explained with reference to FIG. 6.

Firstly, the semiconductor substrate SUB is prepared (first step S1). The semiconductor substrate SUB has a first surface SF1. The semiconductor substrate SUB is prepared as, for example, the SOI substrate.

Secondly, the semiconductor element is formed on the first surface SF1 of the semiconductor substrate SUB (second step S2). In this step, the MOS transistor TR and the above contact element are formed.

Thirdly, the lower interlayer insulation film ILD1 is formed so as to cover the MOS transistor TR on the first surface SF1 (third step S3). The lower interlayer insulation film ILD1 is made of the antiferroelectric. In this step, the lower interlayer insulation film ILD1 is formed by heating to a temperature less than the Curie point. Further, after this step, the lower interlayer insulation film ILD1 is not heated at a temperature above the Curie point of the antiferroelectric. Consequently, the transition of the antiferroelectric configurating the lower interlayer insulation film ILD1 to the ferroelectric is suppressed.

Fourthly, the contact CT and the wiring layer M1 are formed (fourth step S4). A forming method of the wiring layer M1 is, for example, a damascene method. In this way, the semiconductor device 101 shown by FIGS. 2 and 3 is manufactured. In this step, Post-metallization annealing (PMA) may be performed. In this case, heating temperature is set at the temperature less than the Curie point of the antiferroelectric configurating the lower interlayer insulation film ILD1. As a result, a middle interlayer insulation film, a middle wiring layer, an upper interlayer insulation film, an upper wiring layer, and the like are formed.

In the above steps S2 to S4, a layout pattern of each element is formed by using a photoengraving. The layout pattern of each element is designed and verified based on a specification required for the semiconductor device 101.

The layout pattern of each element is designed, for example, based on a result of a circuit simulation simulating an operation of a circuit including the MOS transistor TR or designed by an automatic placement and routing (P & R) program. The circuit simulation is, for example, Simulation Program with Integrated Circuit Emphasis (SPICE).

Note that this fifth step may be performed as an annealing treatment that uses a hot plate. In this case, since the lower interlayer insulation film ILD1 is slowly cooled after heating stop due to the hot plate, a crystal structure of the lower interlayer insulation film ILD1 can be made a single crystal.

In addition, by this fifth step, uniformity of at least any of a film quality and a film thickness of the lower interlayer insulation film ILD1 may also deteriorate. For example, in the lower interlayer insulation film ILD1 after this fifth step, at least any of a large number of aggregates and pores may be included. Therefore, in this fifth step, before the above processing for adjusting the relative dielectric constant, a processing for improving the uniformity of the film quality and the film thickness may be performed. As such a processing, for example, solvents such as chlorobenzene, dimethylformamide, and 1-cyclohexyl-2-pyrrolidone may be spin-coated on a solvent containing a antiferroelectric material spin-coated on the first surface SF1.

### Effects of Semiconductor Device

Effects of the semiconductor device 101 will be explained based on contrast with a comparative example. A semiconductor device according to a first comparative example is different from the semiconductor device 101 only in that an interlayer insulation film is made of a general low dielectric constant material. As described above, a relative dielectric constant of the general low dielectric constant material is 2.6 or more. Therefore, the semiconductor device according to the first comparative example needs to widen a space between two conductors adjacent to each other via the interlayer insulation film in order to suppress the propagation delay and to reduce a capacity value between the above two conductors. Accordingly, in the semiconductor device according to the first comparative example, it is difficult to be compatible with the high integration of the semiconductor elements as well as the miniaturization of each wiring and the suppression of the propagation delay due to them.

In contrast, in the semiconductor device 101, the lower interlayer insulation film ILD1 is made of antiferroelectric. Therefore, in the state in which the external electric field is not applied, the entire electric susceptibility χ of the antiferroelectric configurating the lower interlayer insulation film ILD1 is lower than electric susceptibility of the general low dielectric constant material, and is less than 1. Namely, the minimum value of the relative dielectric constant material of the lower interlayer insulation film ILD1 becomes less than 2. Therefore, capacity between the two adjacent conductors sandwiching the lower interlayer insulation film ILD1 in the semiconductor device 101 (for example, capacity between the first wiring layer and the second wiring layer) becomes lower than capacity between the two adjacent conductors sandwiching the interlayer insulation film made of the general low dielectric constant material in the semiconductor device according to the first comparative example. Accordingly, in comparison with the semiconductor device according to the first comparative example, the semiconductor device 101 realizes the high integration of the semiconductor elements and the miniaturization of each wiring and can simultaneously suppress the propagation delay due to them.

Note that the sizes and spaces of the semiconductor element and the wiring in the semiconductor device 101 may be equal to those of the semiconductor device according to the first comparative example. In this case, the semiconductor device 101 can increase an operating speed in comparison with the that of the semiconductor device according the first comparative example.

In addition, in the semiconductor device according to the first comparative example, since the interlayer insulation film is made of the general low dielectric constant material, it is difficult to suppress occurrence of soft errors due to the cosmic rays. The cosmic rays reaching to the earth from the outer space include secondary neutron beams caused by high energy radiations or by the radiations colliding with atomic nucleus such as oxygen in the atmosphere and destroying them. Energy of those cosmic radiations is several MeV to GeV, destroys atomic nucleus of atom configurating the semiconductor device when entering the semiconductor device, and finally generates a large number of charges (hereinafter, described as abnormal abnormal charges is not charges). The large number of captured by inter-wiring capacitance that uses the interlayer insulation film made of the low dielectric constant material as dielectric, and reaches to the impurity region configurating a memory node in the memory circuit. In an n-type MOS transistor, the abnormal charges reach to the drain.

Specifically, when the atomic nucleus of the atomic is destroyed by the cosmic rays for example, a dipole composed of proton and electron occurs. Energy of the dipole is a 10 MV class just after the occurrence, but attenuates in a process in which a distance between proton and electron increases. When the distance between the both increases to a degree of about a few atoms, the diploe whose energy is a keV class becomes an electron hole pair. The energy weakens at a 10 eV class in a process in which the electron hole pair moves in the semiconductor device, but electron and hole reach to the impurity region configurating the memory node in the memory circuit without being captured by the inter-wiring capacity that uses the interlayer insulation film made of a low dielectric constant material as dielectric. As a result, in the semiconductor device according to the first comparative example, there is a problem in which data retained in the memory node is reversed and the soft error easily occurs.

In contrast, according to the semiconductor device 101, the lower interlayer insulation film ILD1 is made of antiferroelectric, so that only when magnitude of the electric field applied to the lower interlayer insulation film ILD1 by the abnormal charge exceeds the above specific value, the relative dielectric of the lower interlayer insulation film ILD1 becomes higher than the relative dielectric of the lower interlayer insulation film ILD1 at the time of the normal operation. Therefore, a part of the above abnormal charge can be captured by the inter-wiring capacity in which the lower interlayer insulation film ILD1 is used as dielectric. As a result, in the semiconductor device 101, it is possible to be compatible with the high integration of semiconductor and the device the miniaturization of each wiring, the suppression of the propagation delay due to them, and the occurrence suppression of the soft error.

In the semiconductor device 101, the maximum value of the relative dielectric constant of the lower interlayer insulation film ILD1 is above 2.9. Namely, the maximum value of the relative dielectric constant of the lower interlayer insulation film ILD1 becomes higher than the relative dielectric contact of the low dielectric constant material. Such a semiconductor device 101 can suppress the occurrence of the soft error in comparison with the semiconductor device according to the first comparative example. The maximum value of the relative dielectric constant of the element separation film ISL is preferably above 4.3. Namely, the maximum value of the relative dielectric constant of the element separation film ISL becomes higher than the relative dielectric constant of the silicon oxide film. In those semiconductor devices 101, the occurrence of the above soft error can be suppressed in comparison with the semiconductor device according to the first comparative example. Such a semiconductor device 101 is suitable to a technical field in which the high integration of the semiconductor device and the suppression of the above soft error are required simultaneously, for example, is particularly suitable to a field of cars, aerospace systems, medical equipment, and the like. In the aerospace systems, since an effect of the atmosphere to shield the cosmic rays cannot be expected, a case in which even the soft error having a very small possibility of the occurrence is not allowed exists, but the semiconductor device 101 is also suitable to such a case.

In addition, in the semiconductor device according to the first comparative example, the low dielectric constant material in which the plurality of voids is formed is adopted as the interlayer insulation film, it becomes possible to lower the relative dielectric constant of the interlayer insulation film. However, a mechanical strength of the interlayer insulation film in which the plurality of voids formed is lower than a mechanical strength of the interlayer insulation film in which the plurality of voids is not formed. Therefore, when wires are jointed to pads by a wire bonding method, abnormalities such as cracks easily occur in the interlayer insulation film in which the plurality of voids is formed. When the wire layer is formed by a damascene method and the like, abnormalities such as dents easily occur in the interlayer insulation film in which the plurality of voids is formed. Such abnormalities may cause hard errors at the semiconductor device.

In contrast, in the lower interlayer insulation film ILD1 of the semiconductor device 101, the plurality of voids is not formed. The Young's modulus of the lower interlayer insulation film ILD1 is 8 GPa or more, and is higher than the Young's modulus of the porous low dielectric constant material. Therefore, in the semiconductor device 101, the abnormalities such as cracks and dents are unlikely to occur in the lower interlayer insulation film ILD1. Accordingly, in the semiconductor device 101, the occurrence of the hard error can also be suppressed.

Further, in the semiconductor device 101, the film thickness of the lower interlayer insulation film ILD1 is 2 nm or more and 50 nm or less. When the lower interlayer insulation film ILD1 and the interlayer insulation film made of the general low dielectric constant material, whose film thicknesses are equal to each other are compared, the minimum value of the relative dielectric constant of the lower interlayer insulation film ILD1 is lower than the relative constant of the general dielectric constant dielectric material. Therefore, in the semiconductor device 101, if the film thickness of the lower interlayer insulation film ILD1 is equal to the film thickness of the interlayer insulation film ILD of the semiconductor device according to the first comparative example, the capacity value of the lower interlayer insulation film ILD1 at the time of the normal operation can made be smaller than the capacity value of the interlayer insulation film ILD made of the general low dielectric constant material. Meanwhile, in the semiconductor device 101, if the capacity value of the lower interlayer insulation film ILD1 at the time of the normal operation is equal to the capacity value of the interlayer insulation film ILD of the semiconductor device according to the first comparative example, the film thickness of the lower interlayer insulation film ILD1 can be made wider than the film thickness of the interlayer insulation film ILD made of the general dielectric constant material. As a result, in the semiconductor device 101 in comparison with the semiconductor device according to the first comparative example, the reduction of the inter-wiring capacity is achieved and, simultaneously, the reduction of the leak current is possible, so that the high performance can be made.

In the semiconductor device 101, the electric field applied to the pair of adjacent conductors sandwiching the lower interlayer insulation film ILD1 at the time of the normal operation is set less than the electric field at which the spontaneous polarization occurs in the antiferroelectric, so that the relative dielectric constant of the lower interlayer insulation film ILD1 can be retained less than 2 at the time of the normal operation. For example, the electric field applied between the pair of conductors may be less than 50 kV/cm at the time of the normal operation. The electric field at which the spontaneous polarization occurs may be 50 kV/cm or more at the time of the normal operation. Further, in the semiconductor device 101, the external electric field applied to the lower interlayer insulation film ILD1 due to the cosmic rays is set less than the electric field at which the antiferroelectric configurating the lower interlayer insulation film ILD1 is caused to phase-transition to the ferroelectric. Therefore, after the above external electric field is not applied, the relative dielectric constant of the lower interlayer insulation film ILD1 is again made less than 2, and the abnormal charge is gradually released from the lower interlayer insulation film ILD1. As a result, in the semiconductor device 101, even the above external electric field is applied repeatedly after some time, the occurrence of the above soft error can be suppressed each time and the propagation delay can further be suppressed at the time of the normal operation after the above external electric field is removed.

Note that the external electric field equal to or more than the electric field at which the antiferroelectric configurating the lower interlayer insulation film ILD1 caused to phase-transition to the ferroelectric may be applied to the lower interlayer insulation film ILD1. The lower interlayer insulation film ILD1 may transition to the ferroelectric from the antiferroelectric. In this case, a processing for returning the lower interlayer insulation film ILD1 from the ferroelectric to the antiferroelectric is performed, so that the above effect of the lower interlayer insulation film ILD1 can be reproduced in the semiconductor device 101. As the processing for returning the lower interlayer insulation film ILD1 from the ferroelectric to the antiferroelectric, for example, a performing for applying a positive and negative voltage like an alternating current to the lower interlayer insulation film ILD1 and for gradually decreasing this voltage is given. This processing makes it possible to disturb a crystal structure of the ferroelectric and reproduce a crystal structure of the antiferroelectric. As an example of another processing, a processing for heating the lower interlayer insulation film ILD1 and then cooling quickly it is given. This processing makes it possible to break the crystal structure of the ferroelectric and to reproduce the crystal structure of the antiferroelectric.

In addition, in the semiconductor device according to the first comparative example, when the abnormal charge due to the ESD enter the pad, the interlayer insulation film made of a low dielectric constant material cannot capture the above abnormal charge.

In contrast, in the semiconductor device 101, when the ESD pulse enter from the pad, the external electric field equal to or more than 50 kV/cm is applied to the lower interlayer insulation film ILD1 located between the pad and the semiconductor element. As a result, the relative dielectric constant of the lower interlayer insulation film ILD1 becomes higher than the relative dielectric constant of the low dielectric constant material, and a part of the abnormal charge due the ESD can be captured by the inter-wiring capacity that uses the lower interlayer insulation film ILD1 as the dielectric.

FIG. 7 is a circuit drawing showing one example of a circuit including the semiconductor device 101, the current being realized only when the ESD pulse enters from the pad. FIG. 8 is a graph showing a time change of a current flowing in the MOS transistor after the ESD pulse enter the semiconductor device. A solid line in FIG. 8 shows a time change of a current flowing in the MOS transistor TR in the semiconductor device 101, and a dashed line shows a time change of a current flowing in the MOS transistor in the semiconductor device according to the first comparative example. As shown in FIG. 7, the lower interlayer insulation film ILD1 can act as a capacitor for suppressing the followings; the part of the abnormal charge due to the ESD reaches to the MOS transistor TR. Consequently, as shown in FIG. 8, in the semiconductor device 101, a value of the current flowing in the MOS transistor TR can be suppressed less than a threshold value BD of the current at which the

MOS transistor TR is destroyed. As a result, in the semiconductor device 101, the destruction of the semiconductor element due the ESD can be suppressed.

In a step of forming the lower interlayer insulation film ILD1 in a method of manufacturing the semiconductor device 101, a temperature of the lower interlayer insulation film ILD1 is set less than the Curie point of the antiferroelectric configurating the lower interlayer insulation film ILD1, so that the transition of the antiferroelectric configurating the lower interlayer insulation film ILD1 to the ferroelectric can be suppressed.

In the semiconductor device 101, since the lower interlayer insulation film ILD1 does not contact with a gate insulation film GI, it can be suppressed that the charge captured by the lower interlayer insulation film ILD1 reaches to the gate insulation film GI.

### Second Embodiment

A semiconductor device 102 according to a second embodiment has the same configuration, operating principle, and operation and effect as those of the above first embodiment unless otherwise specified. Therefore, the same configuration, operating principle, and operation and effect as the above first embodiment will not be explained repetitively.

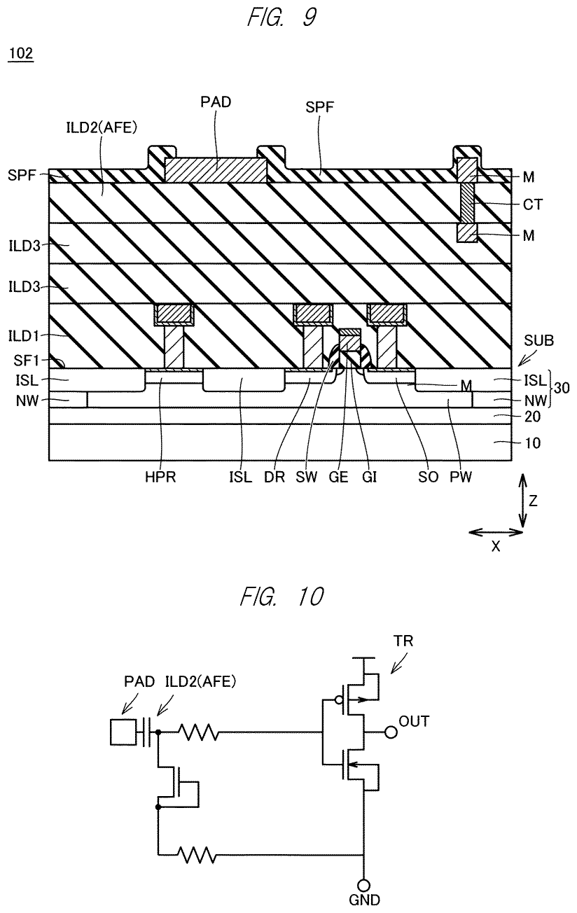

As shown in FIG. 9, the semiconductor device 102 according to the second embodiment is different from the semiconductor device 101 in that the upper interlayer insulation film ILD2 is made of antiferroelectric. The antiferroelectric configurating the upper interlayer insulation film ILD2 has only to be equal to the antiferroelectric configurating the lower interlayer insulation film ILD1 in the semiconductor device 101. When an electric field of 50 kV/cm or more is applied to the pad, the upper interlayer insulation film ILD2 made of the antiferroelectric is provided so that the spontaneous polarization occurs in the antiferroelectric.

The lower interlayer insulation film ILD1 is made of, for example, paraelectric. The antiferroelectric configurating the upper interlayer insulation film ILD2 preferably has an amorphous structure. It is expected that the mechanical strength of this antiferroelectric is higher than the antiferroelectric having a single crystal structure. The antiferroelectric configurating the upper interlayer insulation film ILD2 may have a polycrystalline structure. In this case, it is preferable that each of a plurality of single crystals is bonded without binders in polycrystalline of the antiferroelectric. It is expected that the mechanical strength of the antiferroelectric like this also is higher than that of the antiferroelectric having the single crystal structure.

The semiconductor device 102 has the upper interlayer insulation film ILD2 made of the antiferroelectric, so that the semiconductor device 102 can be compatible with the high integration of semiconductor the element and the miniaturization of each wiring, the suppression of the propagation delay due to them, and the occurrence suppression of the soft error and can suppress the destruction due to the ESD.

FIG. 10 is a circuit diagram showing one example of a circuit realized only when the ESD pulse enters from the pad. As shown in FIG. 10, the upper interlayer insulation film ILD2 is arranged just below a pad PAD, and can be operated as a capacitor for suppressing the followings; a part of the abnormal charge due to the ESD reaches to the MOS transistor TR and the other electronic components. Therefore, a protection ability with respect to the ESD by the antiferroelectric in the semiconductor device 102 is higher than that in the semiconductor device 101.

In addition, similarly about the upper interlayer insulation film ILD2 of the semiconductor device 102, the cracks are unlikely to occur at the time of the wire bonding, and then the dents are unlikely to occur also at a time of forming the wiring layer M1 by a machine method.

In the semiconductor device 102, the lower interlayer insulation film ILD1 may be configured by the above general low dielectric constant material.

Similarly in the semiconductor device 102, the lower interlayer insulation film ILD1 may be configurated by the antiferroelectric. In this case, each of the lower interlayer insulation film ILD1 and the upper interlayer insulation film ILD2 can be operated as a capacitor for suppressing the followings; the part of the abnormal charge due to the ESD reaches to the MOS transistor TR and the other electronic components. Therefore, in the semiconductor device 102, the protection ability with respect to the ESD by the antiferroelectric is higher than those of the configurations shown by FIGS. 8 and 10.

Each of the plurality of interlayer insulation films ILD may be configurated by the antiferroelectric. The antiferroelectric configurating each of the plurality of interlayer insulation films ILD may be the same, and may be different from each other.

### Third Embodiment

A semiconductor device 103 according to a third embodiment has the same configuration, operating principle, and operation and effect unless otherwise particularly. Therefore, the same configuration, operating principle, and operation and effect as those of the above first embodiment will not be explained repeatedly.

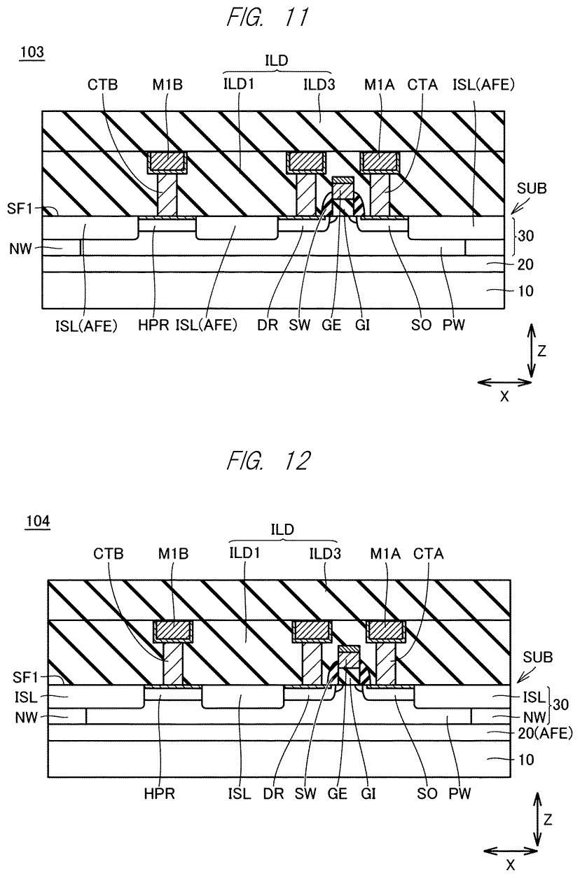

As shown FIG. 11, the semiconductor device 103 according to the third embodiment is different from the semiconductor device 101 in that the element isolation film as well as the lower interlayer insulation film ILD1 are made of antiferroelectric. The antiferroelectric configurating the element separation film has only to be equal to the antiferroelectric configurating lower interlayer insulation film ILD1 in the semiconductor device 101.

The semiconductor device 103 is provided so that a voltage applied between two regions separated by the element separation film ISL at the time of the normal operation becomes less than twice a drive voltage of a MOS transistor TR1 formed in the above region. When the drive voltage of the MOS transistor TR1 is 1 V, the semiconductor device 103 is provided so that the voltage applied between the two regions separated by the element separation film ISL is less than 2 V at the time of the normal operation. when the drive voltage of the MOS transistor TR1 is 3.3 V, the semiconductor device 103 is provided so that the voltage applied between the two regions separated by the interlayer insulation film ILD at the time of the normal operation is less than 6.6 V.

An electric field applied between the two regions separated by the element separation film ILD is, for example, less than 50 kV/cm.

### Effects of Semiconductor Device 103

Effects of the semiconductor device 103 will be explained based on comparison with a comparative example. A semiconductor device according to a second comparative example is different from the semiconductor device 103 only in that the element separation film is made of the general low dielectric constant material. As described above, a relative dielectric constant material of the general low dielectric constant material is 2.6 or more and 2.9 or less. Therefore, in comparison with the semiconductor device having the element separation film made of the dielectric whose relative dielectric constant is above 2.9, the semiconductor device according to the second comparative example can increase the operation speed of the semiconductor element. However, in the semiconductor device according to the second comparative example, when the cosmic rays are incident to a single crystal layer 30 just below the gate insulation film GI, a large number of electron holes occurs on the single crystal layer 30 just below the gate insulation film GI and the source and the drain are conductive to each other. As a result, in the semiconductor device according to the second comparative example, it is difficult to suppress the occurrence of the soft error due to the cosmic rays while suppressing a decrease in the operation speed of the semiconductor element.

In contrast, according to the semiconductor device 103, the element separation film ISL is made of the antiferroelectric, so that only when the magnitude of the electric field applied to the element separation film ISL by the abnormal charge exceeds the above specific value, the relative dielectric constant of the element separation film ISL becomes higher than the relative dielectric constant of the element separation film ISL at the time of the normal operation. Therefore, the part of the abnormal charge can be captured by the element separation film ISL. As a result, the semiconductor device 103 can suppress the occurrence of the soft error while suppressing the decrease in the operating speed of the semiconductor element.

In addition, in the semiconductor device according to the second comparative example, the decrease in the operating speed of the semiconductor element due to the increase in the capacity value of the element separation film is suppressed, so that it is difficult to narrow the width of the element separation film in the X direction or in the Y direction. Namely, in the semiconductor device according to the second comparative example, it is difficult to reduce a chip area while the decrease in the operating speed of the semiconductor element separation film is suppressed. In contrast, in the semiconductor device 103, the element separation film is made of the antiferroelectric, and the minimum value of the relative dielectric constant of the antiferroelectric is less than 2. Therefore, in comparison with the semiconductor device according to the second comparative example, the semiconductor device 103 can suppress the increase in the capacity value of the element separation film even if narrowing the width of the element separation film in the X direction and in the Y direction. As a result, the semiconductor device 103 can reduce the chip area while suppressing the decrease in the operating speed of the semiconductor element.

Note that the size and the interval of the semiconductor element and the wiring in the semiconductor device 103 may be equal to those of the semiconductor device according to the second comparative example. In this case, the semiconductor device 103 can increase the operating speed in comparison with the semiconductor device according to the second comparative example.

Note that the semiconductor device 103 may have the same configuration as that of the semiconductor device 102 except the pint that the element separation film is made of the antiferroelectric.

### Fourth Embodiment

A semiconductor device 104 according to a fourth embodiment has the same configuration, operating principle, and operation and effect as those of the above first embodiment unless otherwise specified. Therefore, the same configuration, operating principle, and operation and effect as the above first embodiment will not be explained repetitively.

As shown in FIG. 12, the semiconductor device 104 according to the fourth embodiment is different from the semiconductor device 101 in that a substrate separation film as well as the lower interlayer insulation film ILD1 is made of antiferroelectric.
The antiferroelectric configurating the substrate separation film may be equal to the antiferroelectric configurating the lower interlayer insulation film ILD1. The semiconductor device 104 is provided so that a voltage applied between a bulk layer 10 and a single crystal layer 30, which are separated by the substrate separation film 20, at the time of the normal operation becomes less than twice a drive voltage of the MOS transistor TR1 formed in the above region. When the drive voltage of the MOS transistor TE1 is 1 V, the semiconductor device 103 is provided so that the voltage applied between the above two regions separated by the substrate separation film 20 at the time of the normal operation is less than 2 V. when the drive voltage of the MOS transistor TR1 is 3.3 V, the semiconductor device 103 is provided so that the voltage applied between the above two regions separated by the substrate separation film 20 at the time of the normal operation is less than 6.6 V.

The voltage applied between the above two regions separated by the substrate separation film 20 at the time of the normal operation is, for example, less than 50 kV/cm.

### Effects of Semiconductor Device 104

Effects of the semiconductor device 104 will be explained based on comparison with the comparative example. The semiconductor device according a third comparative example is different from the semiconductor device 104 only in that the substrate separation film is made of a general low dielectric constant material. As described above, the relative dielectric constant of the general low dielectric constant material is 2.6 or more and 2.9 or less. Therefore, the semiconductor device according to the third comparative example can increase the operating speed of the semiconductor element in comparison with the semiconductor device having the substrate separation film made of the dielectric whose relative dielectric constant is above 2.9. However, in the semiconductor device according to the third comparative example, when the cosmic rays are incident to the single crystal layer just below the gate insulation film GI, a large number of electron hole pairs occur on the single crystal layer 30 just below the gate insulation film GI and the source and the drain are conducted. As a result, in the semiconductor device according to the third comparative example, it is difficult to suppress the occurrence of the soft error due to the cosmic rays while the decrease in the operating speed of the semiconductor element is suppressed.

In contrast, according to the semiconductor device 104, the substrate separation film is 20 made of the antiferroelectric, so that only when the magnitude of the electric field applied to the substrate separation film 20 by the abnormal charge exceeds the above specific value, the relative dielectric constant of the substrate separation film 20 becomes higher than the relative dielectric of the substrate separation film 20 at the time of the normal operation. Therefore, the part of the abnormal charge can be captured by the substrate separation film 20. As a result, the semiconductor device 104 can suppress the occurrence of the soft error while suppressing the decrease in the operating speed of the semiconductor element.

Note that the semiconductor device 104 may have the same configuration as that of the semiconductor device 102 or the semiconductor device 103 except the point that the substrate separation film is made of the antiferroelectric.

As described in the semiconductor device 104, the interlayer insulation film, the element separation film, and the substrate separation that are made of the antiferroelectric may transition to the ferroelectric from the antiferroelectric also in the semiconductor devices 102 to 104. In this case, by performing a processing for returning the interlayer insulation film, the element separation film, and the substrate separation film to the antiferroelectric from the ferroelectric, the above effects realized by the interlayer insulation film, the element separation film, and the substrate separation film being made of the antiferroelectric can be reproduced. As the processing for returning the interlayer insulation film, the element separation film, and the substrate separation film to the antiferroelectric to the ferroelectric, as described above such a processing is given that the positive and negative voltage such as an alternating current is alternately applied to the element separation film and the substrate separation film and, simultaneously, this voltage gradually decreases. This processing makes it possible to disturb the crystal structure of ferroelectric and to reproduce the crystal structure of the antiferroelectric. As another processing example, a processing for heating the element separation film and the substrate separation film and then cooling quickly them is given. This processing makes it possible to destroy the crystal structure of the ferroelectric and to reproduce the crystal structure of the antiferroelectric.

As described above, the invention made by the present inventors has been specifically explained based on the embodiments, but the present invention is not limited to the above embodiments and, needless to say, can be variously modulated within a range of not departing from the gist thereof.

What is claimed is:

1. A semiconductor device comprising a first interlayer insulation film made of antiferroelectric,
wherein a minimum value of a relative dielectric constant of the first interlayer insulation film is less than 2.

2. The semiconductor device according to claim 1,
wherein a maximum value of the relative dielectric constant of the first interlayer insulation film is 2.9 or more.

3. The semiconductor device according to claim 1, wherein a Young's modulus of the first interlayer insulation film is 8 GPa or more.

4. The semiconductor device according to claim 1,
wherein a plurality of voids is not formed in the first interlayer insulation film.

5. The semiconductor device according to claim 1,
wherein a remnant polarization amount of the first interlayer insulation film is 15 μC/cm² or more.

6. The semiconductor device according to claim 1, wherein a material configurating the antiferroelectric is at least any one selected from a group of HfO₂, ZrO₂, Pb(In_{0.5}Nb_{0.5})O₃, NbNaO₃, ZrPbO₃, TiZrLaPbO₃, TiZrPbO₃, NH₄H₂PO₄, or NH₄H₂AsO₄.

7. The semiconductor device according to claim 1,
wherein a film thickness of the first interlayer insulation film is 2 nm or more and 50 nm or less.

8. The semiconductor device according to claim 1, further comprising a pair of conductors sandwiching the first interlayer insulation film,
wherein an electric field applied between the pair of conductors at a time of a normal operation is set less than an electric field at which a spontaneous polarization occurs in the antiferroelectric.

9. The semiconductor device according to claim 8, wherein the electric field applied between the pair of conductors at the time of the normal operation is less than 50 kV/cm.

10. The semiconductor device according to claim 8,
wherein the pair of conductors is a pair of wiring layers arranged apart from the first interlayer insulation film.

11. The semiconductor device according to claim 1, further comprising a pad arranged on the first interlayer insulation film,
wherein when an electric field of 50 kV/cm or more is applied to the pad, a spontaneous polarization occurs in the antiferroelectric.

12. The semiconductor device according to claim 11,
wherein after the application of the electric field is stopped, a polarization amount of the first interlayer insulation film is reduced by 15 μC/cm².

13. The semiconductor device according to claim 1,
wherein when cosmic rays are incident, a spontaneous polarization occurs in the antiferroelectric.

14. The semiconductor device according to claim 13,
wherein the cosmic rays include at least any of particle radiation and high energy electromagnetic radiation,
wherein the particle radiation includes at least any one selected from a group of α rays, β rays, a neutron beam, and a proton beam, and
wherein the high energy electromagnetic radiation includes at least any one of γ rays and X rays.

15. The semiconductor device according to claim 1, further comprising:
a semiconductor substrate having a first surface, wherein the first interlayer insulation film is formed on the first surface; and
a second interlayer insulation film formed between the semiconductor substrate and the interlayer insulation film, wherein the second interlayer insulation film is made of paraelectric.

16. The semiconductor device according to claim 1, further comprising:
a semiconductor substrate having a first surface;
a second interlayer insulation film formed on the first surface, wherein the first interlayer insulation film is formed on the second interlayer insulation film and the first interlayer insulation film has a second surface; and
a pad formed on the second surface, wherein the second interlayer insulation film is made of paraelectric, the antiferroelectric configurating the second surface of the first interlayer insulation film has an amorphous structure or a polycrystalline structure.

17. A semiconductor device comprising:
a semiconductor substrate having a first surface;
a gate electrode formed on the first surface via a gate insulation film;
a sidewall insulation film covering a side wall of each of the gate insulation film and the gate electrode; and
an interlayer insulation film formed on the first surface so as to cover the gate electrode and the sidewall insulation film,
wherein the interlayer insulation film is made of antiferroelectric, and
wherein the interlayer insulation film is spaced from the gate insulation film.

18. The semiconductor device according to claim 17,
wherein the interlayer insulation film contacts with the sidewall insulation film.

19. A method of manufacturing a semiconductor device, the method comprising:
preparing a semiconductor substrate having a first surface;
forming a semiconductor element on the first surface; and
forming an interlayer insulation film, which covers the semiconductor element, on the first surface,
wherein the interlayer insulation film is made of antiferroelectric, and
wherein in the forming of the interlayer insulation film, the interlayer insulation film is formed by heating to a temperature less than the Curie point of the antiferroelectric.

20. The method of manufacturing a semiconductor device according to claim 19,
wherein the forming of the interlayer insulation film includes adjusting a relative dielectric constant of the interlayer insulation film.
